(19) United States
(12) Patent Application Publication
(10) Pub. No.: US 2026/0167133 A1
(43) Pub. Date: Jun. 18, 2026

(54) ELECTRONIC CONTROL UNIT AND METHOD FOR MOUNTING THE ELECTRONIC CONTROL UNIT

(71) Applicant: ZF CV Systems Global GmbH, Bern (CH)

(72) Inventors: Tomasz Slowinski, Wroclaw (PL); Dominik Szczerba, Domaslaw (PL); Michal Wolanski, Wroclaw (PL)

(21) Appl. No.: 19/417,090

(22) Filed: Dec. 11, 2025

(30) Foreign Application Priority Data
Dec. 17, 2024 (EP) 24220704.1

(51) Int. Cl. B60R 16/023; H05K 5/00

(52) U.S. Cl. CPC B60R 16/0239; B60R 16/0231; H05K 5/0069

(57) ABSTRACT

An electronic control unit for controlling application circuits includes: a housing with a front opening, a printed circuit board with electronic components, at least one connector being mounted on a front end of the printed circuit board and extending in a longitudinal direction, a frame including a lower frame part and an upper frame part, wherein the lower frame part and the upper frame part are fixed to each other thereby holding or clamping the connectors therebetween, wherein at least one of the frame parts includes at least two spacers protruding in a vertical direction between two adjacent connectors, thereby holding or clamping the at least one connector, wherein the printed circuit board with the frame is inserted into the front opening of the housing in the longitudinal direction, wherein the frame is fixed to the housing.

### CROSS-REFERENCE TO RELATED APPLICATIONS

This application claims priority of European patent application no. 24220704.1, filed Dec. 17, 2024, the entire content of which is incorporated herein by reference.

### TECHNICAL FIELD

The disclosure relates to an electronic control unit, which is in particular adapted for automotive applications, and to a method for mounting the electronic control unit.

### BACKGROUND

Electronic control units (ECUs) used in automotive applications typically include a printed circuit board with electronic components and a housing that surrounds and protects the printed circuit board (PCB) and the electronic components. In addition, various connectors are mounted on the PCB and extend through a front opening in the housing for contacting the ECU. These ECUs often have electronic connectors only on their front side to facilitate the assembly of the ECU on a vehicle structure, in particular via fixation lugs or fixing tabs of the housing.

The ECUs typically include a variety of different connectors required for specific applications and vehicle models. The connectors can be multipoint or single point connectors, often using customized main housing parts to receive the specific connectors. However, these specific configurations, in particular a large number of different housings and multi point connectors with specific fixing or mounting means, result in high costs and time to create the configurations. Multipoint connectors can be used to combine several connectors or connector types, with the multipoint connector being mounted as a single part on the PCB. Alternatively, individual single connectors can be mounted on the PCB.

### SUMMARY

It is an object of the disclosure to provide an electronic control unit and a method of mounting the electronic control unit which allows easy assembly and low cost without limiting the variety of connectors for use in the electronic control unit.

This object is, for example, solved by an electronic control unit according to various embodiments of the disclosure. Further a method of mounting the electronic control unit is provided.

Thus, the electronic control unit (ECU) according to an embodiment of the disclosure includes a printed circuit board (PCB) with at least one connector, mounted on a front end of the PCB, which are fixed by a frame which secures the connectors, wherein the frame is further used for fixing the PCB with the connectors in the housing. The frame therefore includes a lower frame part and an upper frame part, which are vertically fixed to each other thereby housing or receiving the connectors between them.

This solution allows fast and secure assembly without limiting the number and type of connectors. The connectors can be mounted on the front end of the PCB independently, with a space or distance between them, or with a lateral contact between them, but without the need for specific connector fixing means. The fixation of the connectors is then realized by pushing the frame parts in a vertical direction onto each other, whereby the connectors are fixed or clamped between them, in particular separately. At least one of the frame parts includes at least one spacer which extends or protrudes between two adjacent connectors, thereby fixing the connectors in the transverse direction and increasing the stability.

According to an embodiment, at least one connector is fixed between two of the spacers; preferably, all connectors are fixed between two spacers, respectively.

According to an embodiment, at least two adjacent connectors are separated from each other by one of the spacers. Thus, the spacers separate and fix the connectors, in particular without any further fixing means, thereby providing a safe solution with relatively little effort.

According to various embodiments, two adjacent spacers of the two frame parts are in contact with each other, thereby realizing a clamping or stabilizing contact between the frame parts and a clamping or recess for the connectors.

According to an embodiment, at least two of the connectors differ in at least one of the following characteristics: height, width, number of pins, shape. Thus, a high variety of connectors can be used. In addition, a poka-yoke system can be realized, since two almost identical connector with only one or a few changes inside—position of rib for example, can be distinguished.

The disclosure thus offers the possibility of multiple single connector configurations. A feature of the disclosure is a system of internal fixation frames that surround single connectors of the PCB and provide a snap-in interface for a housing, in particular a standard main housing. Modularity of the frames allows to use different connector configurations within same housing, and there is no longer need to build specific multipoint connector or customized main housing for new applications.

The frame parts can preferably combine several functions:
Firstly, the frame parts are used to clamp and fix the connectors independently of each other. Secondly, the frame parts protect the connectors in the vertical and lateral directions. Thirdly, the frame parts form a closed frame which can then be inserted into the housing and fixed in the housing, in particular via a secure locking mechanism, in particular a snap fit.

Thus, a simple and reliable assembly is possible; according to an embodiment, the two frame parts are pushed in vertical directions onto the connectors, thereby fixing and separating the connectors and locking them together, in particular by a snap fit. The closed frame then houses and covers the connectors. The PCB with the mounted frame is then inserted into the front opening of the housing and fixed in the housing by the frame parts, in particular by snap-fitting. This assembly method is safe and easy to perform.

According to an embodiment, the lower frame part and the upper frame part are fixed to each other by snap fits, in particular snap fits on a rear face since such a snap fit does not protrude on the side faces or other faces when the frame is inserted into the housing. The contact between the spacers already provides a high level of stability; the snap fit between the frame parts enhances and improves this stability. In addition, the fixing of the frame parts inside the housing, in particular the snap fit, further increases the stability of the frame and the mounted connectors.

According to an embodiment, the frame formed by the frame parts is an internal frame which is completely pushed into the housing, which is preferably a standard housing, so that the ECU can be mounted with its standard housing in common applications.

According to an embodiment, the connectors are completely covered not only by the frame parts, but in particular by the housing. Thus, according to an embodiment, the connectors do not protrude from the housing. This protects the connectors from accidental damage. The connectors can then be contacted from the front in the usual way.

The housing and frame parts are preferably made of plastic material, which provides a soft and improved snap fit.

According to a further embodiment, at least one fastening or fixing is realized or improved by additional fastening means like screws or bolts. The use of those additional fastening means can improve the sustainability by improving this assembly without specific tools.

### BRIEF DESCRIPTION OF DRAWINGS

The invention will now be described with reference to the drawings wherein:

FIG. 1 is a perspective front view of an electronic control unit according to an embodiment of the disclosure, in its assembled state;

FIG. 2 shows the ECU of FIG. 1 in its disassembled state;

FIG. 3 is a front view of the ECU, in disassembled state;

FIG. 4 is a perspective rear view of the PCB with connectors and frames, in disassembled state;

FIG. 5 shows the ECU from FIG. 4 after snap fit of the frames;

FIG. 6 shows the ECU after assembly of the frame, before pushing the PCB into the housing; and,

FIG. 7 is a perspective front view of an embodiment with connectors covered by the housing.

### DETAILED DESCRIPTION

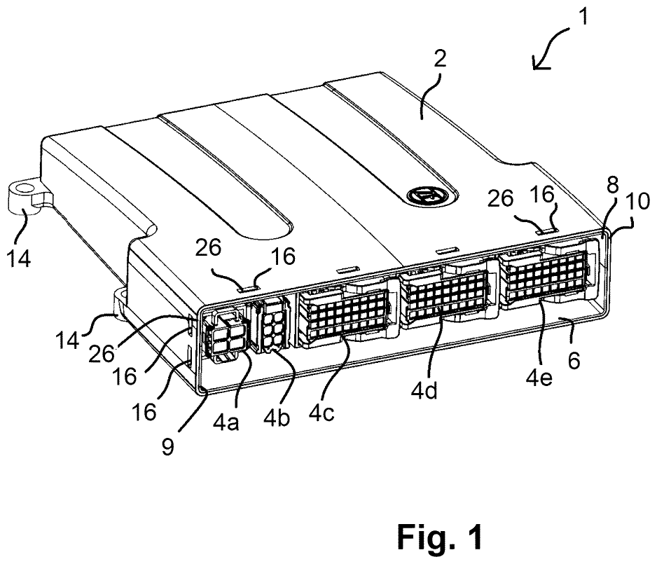

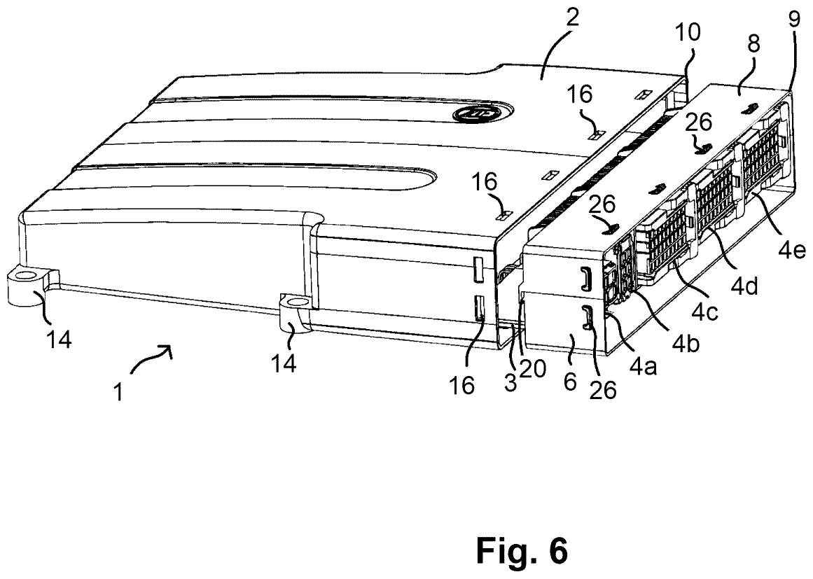

FIGS. 1 to 8 show an electronic control unit 1, hereinafter ECU 1, including a housing 2, preferably made of plastic material, a printed circuit board 3, hereinafter PCB 3, at least one connector 4, for example, five connectors 4, a lower frame part 6 and an upper frame part 8. The housing 2 is preferably closed with only a front opening 10 providing access to its internal space 11, in which sliding guides 12 are provided for receiving the PCB 3. The housing preferably has fastening lugs 14 for mounting it on a vehicle structure, for example. The housing 2 further includes snap fit recesses 16, preferably as snap-in recesses, at its front end, preferably surrounding the front opening 11, in particular on a bottom face, a top face and side faces of the housing 2.

The Cartesian coordinates X, Y, Z refer to a longitudinal direction X, a transverse direction Y and a vertical direction Z. The longitudinal direction X corresponds to the insertion direction for inserting the PCB 3 into the housing 2. In this content, both X and the reverse direction −X refer to as the longitudinal direction; Z and −Z refer to as the vertical direction, and Y and −Y refer to as the transverse direction.

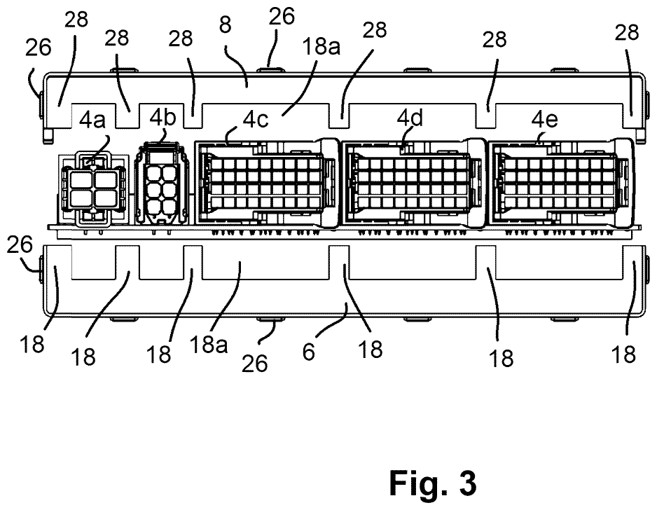

The PCB 3 can be of usual type including printed circuits and electronic components 5. The connectors 4 are mounted on a front end 3a of the PCB 3. The connectors 4 can be of different types, different shapes and different numbers of pins or contacts. The connectors 4 can include multi-connector parts as well as single connectors, as shown in the embodiment. The connectors 4 are mounted on the PCB 3 and contacted with it. The connectors 4 can be separated from each other with no direct contact between them, as can be seen, for example, from the front view of FIG. 3.

The frame parts 6 and 8 fulfil different functions—they are mounted vertically to the front end 3a of the PCB 3, clamping the connectors 4 between them, contacting each other with a form fit, in particular a snap fit, and serving as mounting means for fixing in the housing 2, as described hereinafter.

The frame parts 6 and 8 are made of plastic material, for example, the same plastic material as the housing 2, and are provided with a plurality of recesses and spacers, as explained below. At least one of the frame parts 6, 8, preferably both frame parts 6, 8 have spacers 18, 28 projecting vertically, in particular symmetrically to each other and/or opposing each other, with the same or different length in the vertical direction. In the shown embodiment, the lower frame part 6 has lower spacers 18 projecting upwards and the upper frame part 8 has upper spacers 28 projecting downwards. The lower and upper spacers 18, 28 preferably contact each other and define between them spaces 18a for receiving connectors 4. In the embodiment shown, five connectors 4 of different widths and heights are mounted on the front end 3a of the PCB 3. The connectors 4 can be mounted independently of each other and they can be attached to each other on the side faces, as can be seen from FIG. 3, in which the three larger connectors 4 on the right side can abut each other; however, the connectors 4 can also be mounted with spaces between them, as can be seen from the left part of FIG. 3, with two smaller connectors 4.

The spacers 18, 28 are pushed or shifted into recesses or spaces between or in the connectors 4, thereby fixing, separating and clamping the connectors 4 between the frames 6 and 8. Furthermore, the two frame parts 6, 8 include fixing means 20 for fixing them to each other; in the embodiment shown, the fixing means 20 are realized by a snap fit, for example, with an elastic hook 20a on the upper frame part 8 and a recess 20b for receiving the hook 20a on the lower frame part 6, or vice versa.

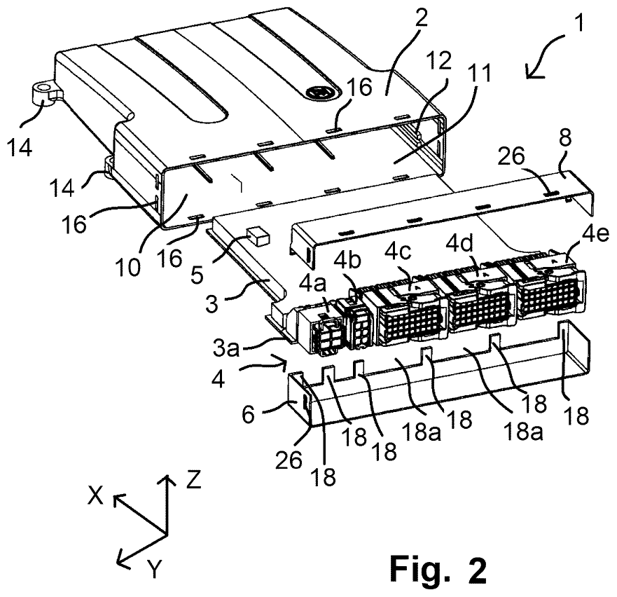

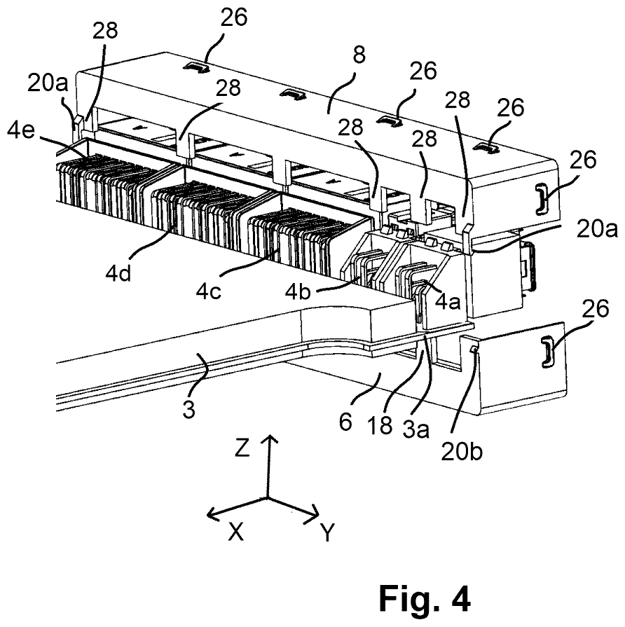

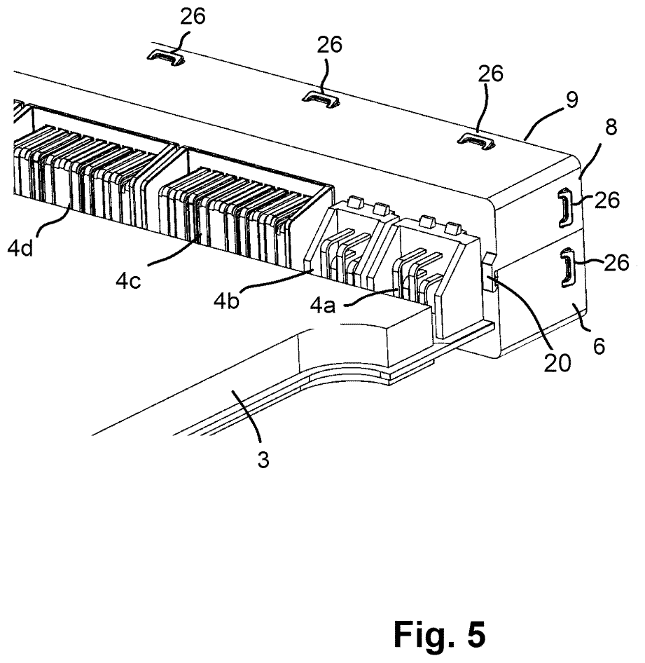

In the first assembly step, starting from the disassembled arrangement of FIGS. 2 and 4, the frame parts 6, 8 are pushed or shifted vertically onto the PCB 3, with the spacers 18, 28 being inserted between the connectors 8, thereby clamping and positively locking them. No further fixing of the connectors 4 is therefore necessary. Furthermore, the snap-fit parts 20a, 20b snap into each other and form the snap-fit 20 of FIG. 5, thereby forming a closed frame 9 with the connectors 4 between them. This arrangement of the printed circuit board 3 with the closed frame 9 is then inserted into the front opening 10, the printed circuit board 3 sliding on the sliding guides 12. The closed frame 9 fits into the front opening 11 and the housing 2 and snap-fits into the housing 2, for this purpose, a further snap fit arrangement is provided on the frame parts 6, 8 and the housing 2; the snap fit recesses 16 distributed on the housing 2 near the front end 10 receive corresponding snap fit protrusions 26 provided on the frame parts 6, 8, thereby enabling a self-locking snap fit. The snap fit protrusion 26 are preferably provided on both frame parts 6, 8, in order to increase the stability. As can be seen from FIG. 2, the recesses 16 and the snap fit protrusions 26 can be distributed on the bottom faces, top faces and side faces of the housing 2 and the frame 9, respectively.

Thus, a quick and secure assembly of the ECU 1 is possible, wherein the frame parts 6, 8 are first pushed onto the front end 3, thereby receiving the connectors 4 between them, and are snap-fitted to one other, thereby forming the closed frame 9. Then the PCB 3 with the frame 9 is shifted or pushed into the front opening 10 until the frame parts 6, 8 snap-fit with their snap-fit protrusion 26 in the recesses 16 of the housing 2. Therefore, no further tools for assembling the ECU 2 are necessary, as can be seen from the FIGS. However, an additional fixing via screws is not necessary but is possible. According to a further embodiment, the snap fit by the snap fit protrusions 26 and recesses 16 can be replaced by a screw fixation, for example, with screws inserted in longitudinal direction X and fixing the frame parts 6, 8 to the housing 2. In such an alternative embodiment, the housing 2 can be provided with suitable fastening lugs or fastening surfaces for receiving the screws. Furthermore, screws can be inserted in the vertical direction Z, −Z.

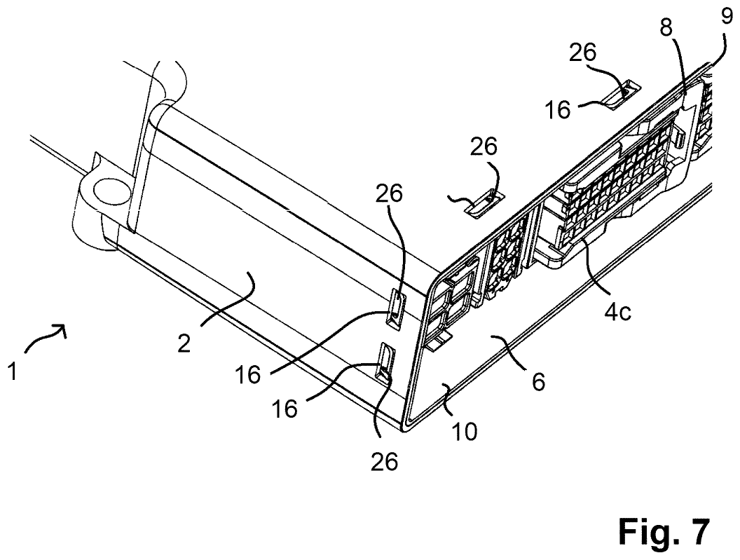

The frame 9 can be pushed completely into the housing 2, as can be seen from the perspective front views of FIGS. 1 and 7. The housing 2 thus serves as a cover and protection for the connectors 4; according to this embodiment, the connectors 4 do not protrude from the housing 2.

The assembled ECU 1 can be disassembled with a specific tool to release the snap fits. In alternative embodiments with screw fixings, the disassembling is simplified, thereby increasing sustainability.

The ECU 1 can be provided for various applications, in particular automotive applications, for example, an ABS controller, a suspension controller, for example, an ECAS suspension controller, a steering controller, an air condition management controller, or a light controller. The snap fit connection can be improved to ensure a watertight configuration. Several electronic components 5, in particular integrated circuits such as electronic control circuits, can be mounted on the PCB 3, for the relevant functions.

In the embodiment shown, five connectors 4a, 4b, 4c, 4d and 4e are provided, which can have different widths in transverse direction Y, different heights in vertical direction Z and different numbers of pins or contacts.

It is understood that the foregoing description is that of the preferred embodiments of the invention and that various changes and modifications may be made thereto without departing from the spirit and scope of the invention as defined in the appended claims.

### LIST OF REFERENCE NUMERALS (PART OF THE DESCRIPTION)

1 electronic control unit
2 housing
3 PCB (printed circuit board)
3a front end of the PCB 3
4, 4a, 4b, 4c, 4d, 4e connectors
5 electronic components
6 lower frame part
8 upper frame part
9 frame
10 front opening
11 internal space
12 sliding guides
14 fastening lugs
16 snap-fit recesses
18 lower spacers
18a spaces between the spacers 18
20 fixing means
20a hook
20b recess
26 snap-fit protrusions
28 upper spacers
X, Y, Z Cartesian coordinates
X longitudinal direction
Y transversal direction
Z, −Z vertical direction

1. An electronic control unit for controlling application circuits, said electronic control unit comprising:
a housing defining a front opening;
a printed circuit board with electronic components;
at least one connector mounted on a front end of said printed circuit board and extending in a longitudinal direction;
a frame including a lower frame part and an upper frame part, wherein said lower frame part and said upper frame part are fixed to each other thereby holding or clamping said connectors therebetween;
wherein at least one of said upper frame part and said lower frame part includes at least two spacers protruding in a vertical direction, said at least two spacers holding, clamping or contacting said at least one connector between them;
wherein said printed circuit board with said frame is inserted into said front opening of said housing in said longitudinal direction; and,
said frame being fixed to said housing.

2. The electronic control unit of claim 1, wherein said at least one connector is fixed between two of said at least two spacers.

3. The electronic control unit of claim 1, wherein the electronic control unit includes at least two connectors; and, at least two adjacent ones of said at least two connectors are separated from each other by one of said at least two spacers.

4. The electronic control unit of claim 1, wherein the electronic control unit includes at least two connectors; and, at least two of said at least two connectors differ in at least one of: height, width, number of pins, and shape.

5. The electronic control unit of claim 1, wherein said at least two spacers from one of said upper frame part and said lower frame part contacts an other of said upper frame part and said lower frame part thereby defining a contact between said upper frame part and said lower frame part and defining a space for receiving one of said at least one connector.

6. The electronic control unit of claim 1, wherein said at least two spacers from one of said upper frame part and said lower frame part contacts an opposing one of said at least two spacers of an other of said upper frame part and said lower frame part thereby defining a contact between said upper frame part and said lower frame part and defining a space for receiving one of said at least one connector.

7. The electronic control unit of claim 1, wherein said lower frame part and said upper frame part are fixed to each other by a snap-fit.

8. The electronic control unit of claim 6, wherein said snap-fit is on a rear side.

9. The electronic control unit of claim 6, wherein said snap-fit is a snap-fit with a hook and a recess for receiving the hook when inserted in the vertical direction.

10. The electronic control unit of claim 1, wherein said frame is fixed in said housing by a housing snap-fit between said frame and said housing, said frame being inserted into said housing in the longitudinal direction and being locked in said housing from inside.

11. The electronic control unit of claim 10, wherein said frame is locked in said housing from inside by a snap-fit.

12. The electronic control unit of claim 10, wherein said housing snap-fit is realized by a plurality of snap-fit protrusions and snap-fit recesses surrounding said housing and said frame.

13. The electronic control unit of claim 1, wherein said at least one connector is covered by at least one of said housing and said frame in the vertical direction, said at least one connector not protruding from said housing.

14. A method for assembling an electronic control unit, the electronic control unit including a housing defining a front opening, a printed circuit board with electronic components, at least one connector mounted on a front end of said printed circuit board and extending in a longitudinal direction, a frame including a lower frame part and an upper frame part, wherein the lower frame part and the upper frame part are fixed to each other thereby holding or clamping the at least one connector therebetween; wherein at least one of the upper frame part and the lower frame part includes at least two spacers protruding in a vertical direction, the at least two spacers holding, clamping or contacting the at least one connector between them; wherein the printed circuit board with the frame is inserted into the front opening of the housing in the longitudinal direction; and, the frame being fixed to the housing, the method comprising:
providing the printed circuit board with the electronic components, the lower frame part, the upper frame part, and the housing with the front opening;
mounting the at least one connector on the front end of the printed circuit board and contacting the at least one connector with the printed circuit board, the at least one connector protruding from the printed circuit board in the longitudinal direction;
mounting the lower frame part and the upper frame part in the vertical direction onto each other thereby receiving the at least one connector between lower frame part and the upper frame part, wherein the lower frame part and the upper frame part are fixed to each other and form a frame surrounding or clamping the at least one connector, two spacers of the at least two spacers defining a space for receiving the at least one connector; and,
shifting or pushing the printed circuit board with the mounted frame into the front opening of the housing and fixing the frame in the housing.

15. The method of claim 14, wherein at least two connectors are provided in adjacent positions, and wherein one spacer of the at least two spacers extends between said two adjacent ones of the at least two connectors.

16. The method of claim 14, wherein the upper frame part and the lower frame part are fixed to each other by a snap-fit.

17. The method of claim 16, wherein the snap-fit locks in the vertical direction.

18. The method of claim 14, wherein an assembly of said upper frame part and the lower frame part and fixing of the frame in the housing is realized without further tools.

19. The method of claim 14, wherein an assembly of said upper frame part and the lower frame part and fixing of the frame in the housing is realized without further tools by snap-fits for self-locking.
